(19) United States
(12) Patent Application Publication
(10) Pub. No.: US 2010/0053868 A1
(43) Pub. Date: Mar. 4, 2010

(54) HEAT DISSIPATION DEVICE

(75) Inventors: JIAN YANG, Shenzhen City (CN); JING ZHANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/200,889

(22) Filed: Aug. 28, 2008

(51) Int. Cl. H05K 7/20

(52) U.S. Cl. 361/679.5

(57) ABSTRACT

A heat dissipation device is provided for being mounted on a computer enclosure to seal an inside of the enclosure from an outside of the enclosure. The heat dissipation device comprises a housing, a plurality of fins received in the housing, and two fans respectively fixed on a top and a bottom of the housing. The plurality of fins divides an inner space of the housing into two separate chambers, wherein a lower chamber communicates with the interior of the enclosure, and an upper chamber communicates with the exterior of the enclosure. A lower fan forces airflow through the lower chamber to take heat in the enclosure to the fins. An upper fan forces airflow through the upper chamber to carry the heat in the fins to the exterior of the enclosure.

### BACKGROUND OF THE INVENTION

1. Field of the Invention

The present invention relates to heat dissipation, and more particularly to a heat dissipation device for use with an outdoor computer.

2. Description of Related Art

With developments in technology, electronic components operate at increasingly high frequencies for enhanced performance thereof. However, heat generated by the electronic component increases correspondingly, which can adversely affect performance and even cause permanent damage.

Conventional computers normally comprise such heat-generating electronic components received in an enclosure thereof. To ensure normal operation, heat dissipation is required, often in the form of a device mounted on the electronic component generating the most heat, removing heat therefrom to the interior of the enclosure. The heat dissipation device often comprises a base contacting the electronic component, absorbing the heat therefrom, and a plurality of fins extending from the base and dispersing the heat from the base. The air in the enclosure, now heated, flows to the exterior of the enclosure via apertures in the enclosure beforehand. Simultaneously, due to air pressure differential between the interior and exterior, cool air is drawn into the enclosure via the apertures, absorbing heat from the heat dissipation device anew. The circulating airflow allows the electronic component to function within its normal temperature.

The heat dissipation device described is suitable for an indoor computer, with the apertures in the enclosure thereof workable and safe, since there is no major dust-proof requirement in the indoor environment. However, for use in an outside environment, air filtration is imperative, requiring that all of the apertures in the enclosure to be blocked. The completely sealed enclosure presents a closed system without air convection between the interior and the exterior of the enclosure, rendering heated air in the enclosure difficult to dissipate, whereby the temperature in the enclosure increases dramatically, resulting in possible malfunction of, or even damage to, the electronic component.

What is needed, therefore, is a heat dissipation device which can overcome the discussed limitations.

### SUMMARY OF THE INVENTION

A heat dissipation device for a computer enclosure seals the interior of the enclosure from the outside. The heat dissipation device comprises a housing, a plurality of fins received in the housing, and two fans respectively fixed on a top and a bottom of the housing. The plurality of fins divides an inner space of the housing into two separate chambers, wherein a lower chamber communicates with the interior of the enclosure, and an upper chamber communicates with the exterior of the enclosure. A lower fan forces airflow through the lower chamber to convey heat in the enclosure to the fins. An upper fan forces airflow through the upper chamber to carry the heat via the fins to the exterior of the enclosure. With the substantial sealing of the enclosure, heat dissipation is provided via two forced airflows, thereby effectively and rapidly removing heat from the enclosure, with temperature in the enclosure maintained at a preferred level, with normal operation of electronic components in the enclosure accordingly achieved.

Other advantages and novel features of the present invention will become more apparent from the following detailed description when taken in conjunction with the accompanying drawings.

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an assembled view of a heat dissipation device in accordance with a preferred embodiment of the present invention.

FIG. 2 is an exploded view of FIG. 1.

FIG. 3 is a cross-section of FIG. 1.

FIG. 4 is an end view of FIG. 1, with the heat dissipation device mounted on an enclosure of an outdoor computer.

### DETAILED DESCRIPTION OF THE INVENTION

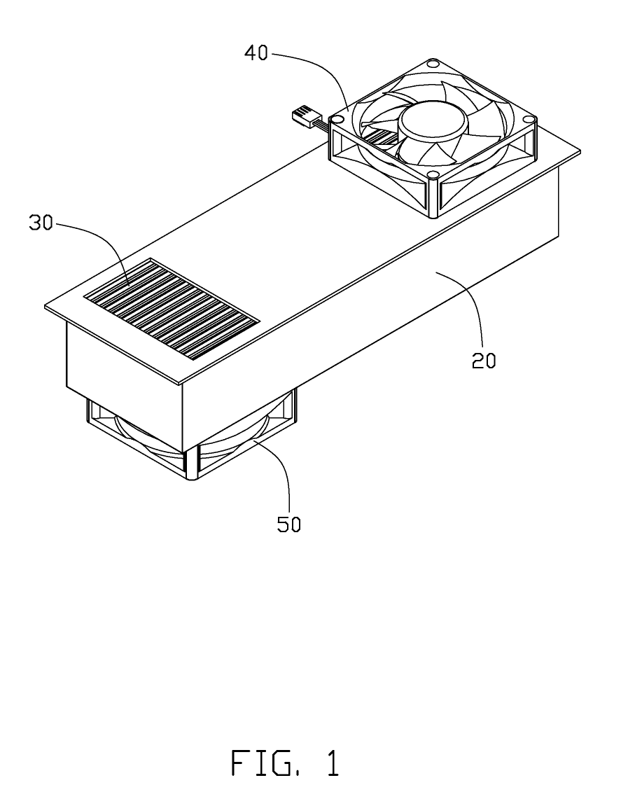

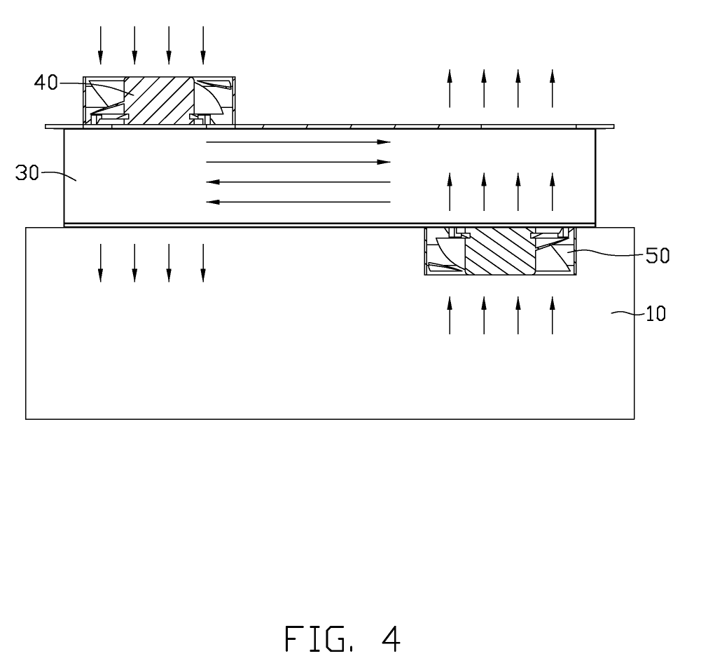

FIGS. 1 and 4 show a heat dissipation device in accordance with a preferred embodiment of the present invention for use with an outdoor electronic device, such as a computer (not labeled). The outdoor computer comprises an enclosure 10 (shown in FIG. 4) and a plurality of electronic components (not shown) received therein. The enclosure 10 defines a window (not labeled) in a corresponding portion thereof. In accordance with conditions of outdoor use, the enclosure 10 is completely sealed, due to the heat dissipation device being mounted on the window, protecting the electronic components from contaminants or moisture in the outdoor environment, such that interior of the enclosure 10 is substantially isolated from the exterior.

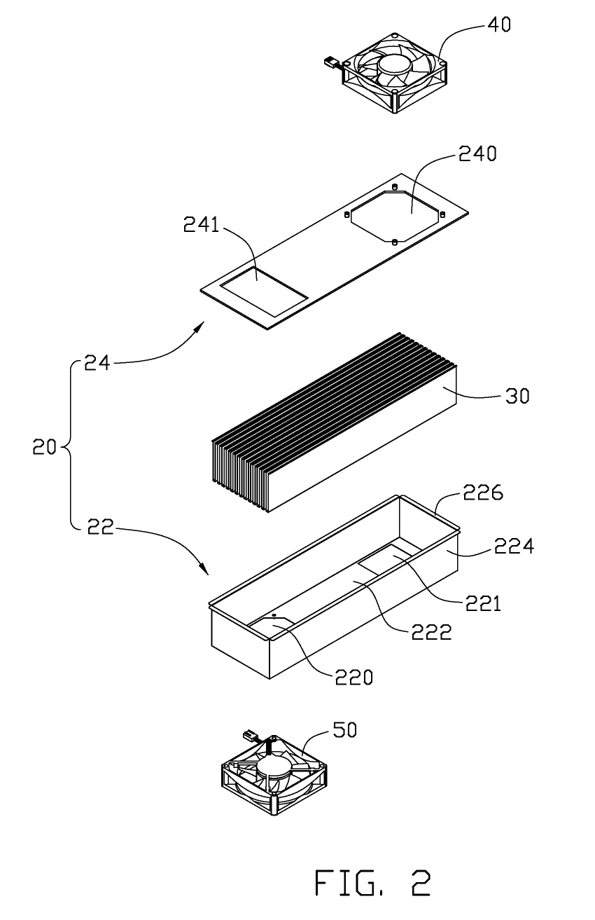

Referring to FIG. 2, the heat dissipation device comprises a housing 20, a plurality of fins 30 received therein, and a pair of fans 40, 50 fixed on a top and a bottom of the housing 20, respectively. The housing 20 comprises a frame 22 accommodating the fins 30 therein and a cover 24 fixed on the frame 22. The frame 22 includes a bottom plate 222, four sidewalls 224 extending upwardly and perpendicularly from a periphery thereof, and four flanges 226 extending outwardly and horizontally from top ends of the four sidewalls 224, respectively. The four flanges 226 are discrete from each other near four joints of the four sidewalls 224. The bottom plate 222 defines two openings 220, 221 adjacent to two lateral ends thereof, respectively, wherein one opening 221 is rectangular, and another opening 220 is octagonal. The octagonal opening 220 allows airflow into the housing 20 from the enclosure 10, and the rectangular opening 221 allows airflow out of the housing 20 into the enclosure 10.

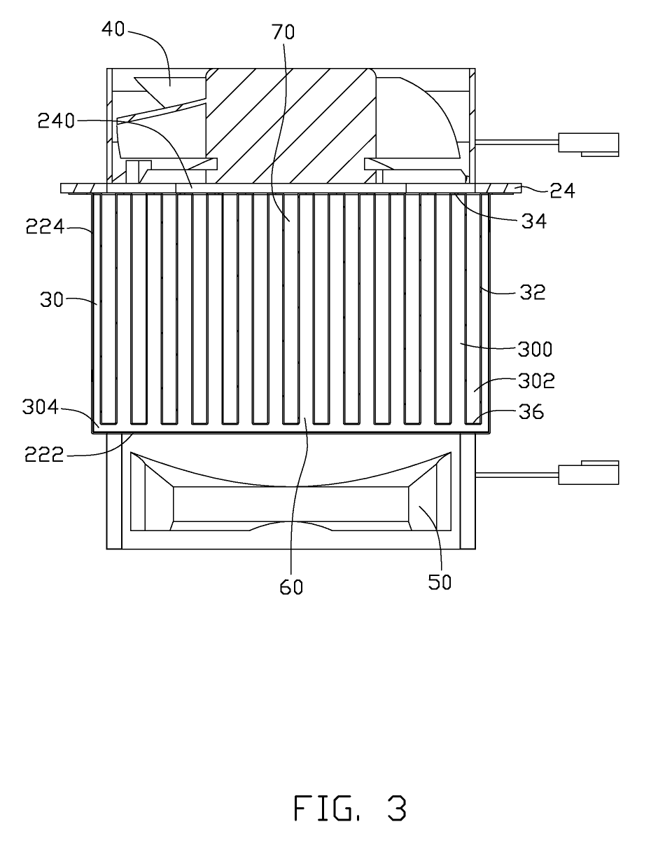

A lower fan 50 is fixed on a bottom face of the bottom plate 222 with its airflow outtake (not labeled) oriented toward the octagonal opening 220, enforcing airflow into the housing 20. The octagonal opening 220 has an area identical to that of the outtake of the fan 50, allowing as much airflow into the housing 20 as possible. The cover 24 is secured on the flanges 226 of the frame 22 by soldering. The cover 24 has an annular outermost part (not labeled) extending beyond the reach of the flanges 226 (as viewed from FIG. 3), enabling the cover 24 to be stably seated on the flanges 226. Similar to the bottom plate 222 of the frame 22, the cover 24 also defines rectangular and octagonal openings 241, 240 approximate to two lateral ends thereof; however, the positions of the two openings 240, 241 in the cover 24 are reversed in respect to the two openings 220, 221 in the bottom plate 222, that is, the rectangular opening 241 in the cover 24 faces the octagonal opening 220 in the bottom plate 22, and the octagonal opening 240 in the cover 24 faces the rectangular opening 221 in the bottom plate 222. An upper fan 40 is secured on the cover 24 with an airflow outtake (not labeled) thereof oriented towards the octagonal opening 240 in the cover 24, whereby the upper fan 40 is staggered with the lower fan 50 in a direction parallel to a lengthwise direction of the housing 20. Since the two openings 240, 241 in the cover 24 communicate the interior of the housing 20 with the exterior, airflow produced by the upper fan 40 can enter the housing 20 from outside of the enclosure 10 via the octagonal opening 240 and then exit to the exterior of the enclosure 10 via the rectangular opening 241.

Also shown in FIG. 3, the fins 30 consist of a folded thin metal sheet, being continuous from beginning to end, and are retained in the housing 20 to divide the interior of the housing 20 into two separate spaces (not labeled). Airflow produced by the upper fan 40 is confined by the fins 30 to flow in an upper space, independent of the airflow produced by the lower fan 50 in a lower space. The fins 30 comprise a plurality of rectangular first portions (not labeled) and a plurality of rectangular second portions (not labeled) alternating with the first portions. Each first portion of the fins 30 includes two vertical parallel vanes 32 and a horizontal upper strip 34 connecting with two top ends of the vanes 32, respectively. The upper strips 34 are soldered on a bottom face of the cover 24 to fix the fins 30 thereon. The two vanes 32 and the upper strip 34 of each first portion of the fins 30 together enclose an elongated first channel 300, which communicates with an adjacent first channel 300 via a chamber 304 surrounded by a lower part of the four sidewalls 224 and a top face of the bottom plate 222. The chamber 304 communicates with the interior of the enclosure 10 via the openings 220, 221 in the bottom plate 22, allowing air in the enclosure 10 to circulate through the first channels 300. The first channels 300 together with the chamber 304 and the interior of the enclosure 10 define a first airflow pathway (not labeled), allowing the airflow generated by the lower fan 50 flowing therealong. Each second portion is constructed by the two vertical parallel vanes 32 and a horizontal lower strip 36 coupling with two bottom ends of the vanes 32, respectively. Each lower strip 36 of the fins 30 is located above the top face of the bottom plate 222, defining a depth of the chamber 304. The lower strip 36 and the two vanes 32 of each second portion of the fins 30 together enclose a second channel 302. Note that only some of the second channels 302 just below the two openings 240, 241 in the cover 24 communicate with the exterior via the openings 240, 241 in the cover 24, while other second channels 302 in other places are isolated from each other as well as the exterior. The some of the second channels 302 together with the exterior of the enclosure 10 define a second airflow pathway, allowing airflow generated by the upper fan 40 circulating therealong.

In use, the two fans 40, 50 generate airflow into the housing 20 through the octagonal openings 220, 240 in the cover 24 and the frame 22, respectively. Airflow generated by the upper fan 40 flows through the fins 30 via the second channels 302 along a first transverse direction (as shown by right-directed arrows in FIG. 4), and airflow generated by the lower fan 50 flows through the fins 30 via the first channels 300 along a second transverse direction opposite to the first transverse direction (as shown by left-directed arrows in FIG. 4). Airflow from lower fan 50 conveys heat generated by the electronic components in the enclosure 10 to the fins 30 when flowing through the first channels 300, while airflow from upper fan 40 conveys heat from the fins 30 to the exterior when flowing through the second channels 302. In this way, the heat generated by the electronic component sealed in the enclosure is indirectly but rapidly dissipated to the exterior by the heat dissipation device.

By applying an initiative heat dissipation structure, i.e., the two fans 40, 50, the air sealed in the enclosure 10 is circulated quickly and heat thus dissipated to the exterior effectively. Compared with the conventional heat dissipation device using passive heat dissipation, the disclosed heat dissipation device maintains temperature of the air in the enclosure 10 within an acceptable range, and electronic components housed therein are protected accordingly.

Alternatively, it is can be apprehended that the upper fan 40 and the lower fan 50 capable of being placed at other positions in the second airflow pathway and the first airflow pathway, respectively, so far as the same functionality thereof are provided. For example, the upper fan 40 can be seated above the rectangular opening 241 in the cover 24 with its airflow intake (not labeled) facing the rectangular opening 241, sucking the airflow in the housing 20 to the exterior of the enclosure 10, the lower fan 50 can be mounted below the rectangular opening 221 in the bottom plate 222 with its airflow intake (not labeled) facing the rectangular opening 221, drawing the airflow in the housing 20 to the interior of the enclosure 10.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

1. A heat dissipation device for a computer enclosure, which, when mounted thereon, substantially seals the enclosure, the heat dissipation device comprising:
a housing,
a plurality of fins received in the housing and dividing an interior of the housing into two separate spaces, wherein a lower one of the two separate spaces communicates with an interior of the enclosure, and an upper one of the two separate spaces communicates with an exterior of the enclosure; and
two fans mounted on a top plate and a bottom plate of the housing, respectively;
wherein airflow generated by the lower of the two fans conveys heat through the lower of the two spaces in the enclosure to the plurality of fins, and airflow generated by the upper of the two fans conveys heat absorbed by the plurality of fins through the upper of the two spaces in the enclosure to the exterior,
wherein the fins comprise a plurality of parallel vanes and upper strips and lower strips alternating with the upper strips, the upper strips each interconnecting top ends of two corresponding neighboring vanes, and the lower strips each interconnecting bottom ends of two corresponding neighboring vanes; and
wherein the upper strips are fixed on a bottom face of the top plate of the housing, and the lower strips are spaced by a chamber from a top face of the bottom plate of the housing, the chamber communicating with the interior of the enclosure.

2. The heat dissipation device as claimed in claim 1, wherein airflow generated by the lower of the two fans flows in a direction opposite the airflow generated by the upper of the two fans.

3. The heat dissipation device as claimed in claim 1, wherein the upper of the two fans is staggered with the lower of the two fans in a direction parallel to a longitudinal axis of the housing.

4. The heat dissipation device as claimed in claim 1, wherein the plurality of fins comprises a folded continuous metal sheet.

5. (canceled)

6. (canceled)

7. (canceled)

8. (canceled)

9. The heat dissipation device as claimed in claim 1, wherein the top plate and the bottom plate of the housing both define two openings therein, the two openings in the top plate aligning with the two openings in the bottom plate of the housing, respectively.

10. The heat dissipation device as claimed in claim 9, wherein the upper of the two fans is mounted above one of the two openings in the top plate, and the lower of the two fans is mounted below one of the two openings in the bottom plate.

11. The heat dissipation device as claimed in claim 9, wherein one of the two openings is rectangular, and the other is octagonal.

12. An electronic device comprising,
a computer enclosure; and
a heat dissipation device mounted on the enclosure to separate an inside space of the enclosure from an outside space of the enclosure, the heat dissipation device comprising:
a housing comprising a frame and a cover mounted on the cover;
a folded sheet mounted in the housing to separate an inside of the housing into a first space and a second space, the first space fluidly communicating with the inside space of the enclosure to cooperatively define a first airflow pathway, and the second space fluidly communicating with the outside space of the enclosure to cooperatively define a second airflow pathway;
a first fan located in the first airflow pathway to speed an airflow within the enclosure; and
a second fan located in the second airflow pathway to speed an airflow outside of the enclosure;
wherein the folded sheet comprises a plurality of parallel vanes and a plurality of horizontal strips interconnecting the plurality of vanes, respectively, every two adjacent ones of the plurality of horizontal strips of the folded sheet are staggered with each other at an upper level and a lower level, respectively, and
wherein the horizontal strips at the upper level are fixed to a bottom face of the cover of the housing, and the horizontal strips at the lower level are spaced by a chamber from a top face of a bottom plate of the frame of the housing.

13. The electronic device as claimed in claim 12, wherein a direction of the airflow speeded by the first fan is opposite to that of the airflow speeded by the second fan.

14. (canceled)

15. (canceled)

16. The electronic device as claimed in claim 12, wherein the first fan is secured on a bottom of the frame and the second fan is secured on a top of the cover.

17. The electronic device as claimed in claim 16, wherein two openings are defined in each of the cover and the frame, the first fan covering one of the two openings in the frame and the second fan covering one of the two openings in the cover.
